(19) United States
(12) Patent Application Publication
(10) Pub. No.: US 2026/0327519 A1
(43) Pub. Date: Oct. 22, 2026

(54) WAFER CLEANING SOLUTION AND METHOD FOR CLEANING WAFER

(71) Applicant: Mu-tech Precision Co., Ltd., Kaohsiung City (TW)

(72) Inventors: Chih-Jen Yang, Kaohsiung City (TW); Kuo-Chang Shih, Kaohsiung City (TW); Fan-Ching Chang, Kaohsiung City (TW)

(73) Assignee: Mu-tech Precision Co., Ltd., Kaohsiung City (TW)

(21) Appl. No.: 19/180,880

(22) Filed: Apr. 16, 2025

(51) Int. Cl. C11D 3/32; C11D 3/00; C11D 3/43; H01L 21/02

(52) U.S. Cl. CPC C11D 3/32; C11D 3/0047; C11D 3/43; H10P 70/30; C11D 2111/22; C11D 2111/44; C11D 2111/46

(57) ABSTRACT

Provided are a wafer cleaning solution and a method for cleaning a wafer. The wafer cleaning solution comprises water, an alkanolamide compound; and a glycol ether solvent; the glycol ether solvent comprises ethylene glycol mono-tert-butyl ether, diethylene glycol monobutyl ether or a combination thereof; wherein a ratio of a total weight of the alkanolamide compound and the glycol ether solvent to a weight of the water is from 1:5 to 1:9.5; wherein a weight ratio of the alkanolamide compound to the glycol ether solvent is from 1:20 to 1:1.5. The method for cleaning a wafer comprises step (a): providing a diced wafer which comprises a plurality of dies; step (b): providing the wafer cleaning solution, and performing a washing process to the diced wafer with the wafer cleaning solution to obtain a washed wafer; and step (c): performing a rinsing process to the washed wafer with water to obtain a cleaned wafer.

### BACKGROUND

### 1. Field of the Invention

The instant disclosure relates to a wafer cleaning solution, more particularly to a wafer cleaning solution applied in a cleaning process after the wafer dicing process. The instant disclosure also relates to a method for cleaning a wafer by using the above-mentioned wafer cleaning solution.

### 2. Description of the Prior Arts

In conventional integrated circuit (IC) manufacturing processes, integrated circuits or bumps are usually formed on a silicon wafer first, and then the silicon wafer is placed on a dicing tape. After that, the silicon wafer is diced into a plurality of dies. During the wafer die sawing process, the edges of the dies inevitably have some chipping or cracking, and some contaminants to be removed, such as tape residue, impurities and debris, are still attached to the surface of the dies. In addition, the exposed surfaces of the dies easily produce copper oxide or copper silicide. If those materials to be removed, such as the aforesaid particles and surface products, are not removed, the subsequent manufacturing process will be affected, and even the circuit short circuit problem will occur in the packaging stage, thereby detrimentally impacting the performance, reliability and/or yield of the resulting products.

In order to remove aforesaid materials to be removed, people in the industry often clean aforesaid materials produced in the die sawing process by spraying pure water. However, due to the use of new materials in the process or the miniaturization of the size of the scribe lines, even though the amount of pure water used for cleaning is increased, the cleaning result is still unsatisfactory. Or, it may be necessary to purchase new wafer dicing equipment to reduce the generation of the debris or to remove the debris directly so that the cost of the overall manufacturing process will be increased.

### SUMMARY OF THE INVENTION

In view of that the conventional wafer cleaning solution and the method for cleaning a wafer cannot meet the requirement of the wafer cleaning process after the wafer dicing process, an objective of the instant disclosure is to provide a wafer cleaning solution; the wafer cleaning solution can allow the cleaning process after the wafer dicing process to be completed simply and quickly without the need for a large amount of water, thereby improving the efficiency of the overall manufacturing process and helping to maintain the quality of subsequent applications.

Another objective of the instant disclosure is to provide a wafer cleaning solution which neither limits the specifications of dicing equipment nor requires purchasing complex and expensive dicing equipment. Thus, the manufacturing cost can be decreased, thereby improving the potential of developing commercial products.

To achieve the above-mentioned objective, the instant disclosure provides a wafer cleaning solution. The wafer cleaning solution comprises water; an alkanolamide compound; and a glycol ether solvent. The alkanolamide compound comprises ethanolamine (MEA), diethanolamine (DEA) or a combination thereof; the glycol ether solvent comprises ethylene glycol mono-tert-butyl ether (ETB), diethylene glycol monobutyl ether (DB) or a combination thereof. Wherein a ratio of a total weight of the alkanolamide compound and the glycol ether solvent to a weight of the water is from 1:5 to 1:9.5; wherein a weight ratio of the alkanolamide compound to the glycol ether solvent is from 1:20 to 1:1.5.

By combining the specific alkanolamide compound and the specific glycol ether solvent with water at the same time and aforesaid components with specific content ratio ranges, the wafer cleaning solution of the instant disclosure can effectively remove the contaminants to be removed, such as residues (for example: tape residue), impurities and silicon debris, which are attached to the surface of the dies after the completion of dicing process; moreover, the wafer cleaning solution of the instant disclosure can prevent the formation of copper oxides and/or copper silicides on the sides of the dies and avoiding chemical reactions. Therefore, the resulting cleaned wafer can have the advantage of improved yield in subsequent applications.

Preferably, the ratio of the total weight of the alkanolamide compound and the glycol ether solvent to the weight of the water may be from 1:5.25 to 1:9.5, but it is not limited thereto. More preferably, the ratio of the total weight of the alkanolamide compound and the glycol ether solvent to the weight of the water may be from 1:7.5 to 1:9.5; for example, 1:7.6, 1:8.2, 1:9.2, or 1:9.3.

Preferably, the weight ratio of the alkanolamide compound to the glycol ether solvent may be from 1:5 to 1:2, but it is not limited thereto. More preferably, the weight ratio of the alkanolamide compound to the glycol ether solvent may be from 1:4 to 1:2.5.

In some embodiments, the alkanolamide compound may be the combination of MEA and DEA; wherein a weight ratio of MEA to DEA may be from 2:1 to 5:1, but it is not limited thereto. Preferably, in the above-mentioned combination, the weight ratio of MEA to DEA may be from 2:1 to 4:1.

In some embodiments, the glycol ether solvent may be the combination of ETB and DB; wherein a weight ratio of ETB to DB may be from 1:1 to 1:4, but it is not limited thereto. Preferably, in the above-mentioned combination, the weight ratio of ETB to DB may be from 1:1 to 1:2.

In some embodiments, the wafer cleaning solution may consist of water, the alkanolamide compound and the glycol ether solvent, but it is not limited thereto. For example, the wafer cleaning solution may consist of MEA, DB and water. Or, the wafer cleaning solution may consist of DEA, DB and water.

Preferably, the ethanolamine may be 2-aminoethanol.

To take into account the diverse convenience of subsequent applications of the wafer cleaning solution of the instant disclosure, the wafer cleaning solution may further comprise auxiliary additives to meet different needs in the case without impacting the main effect. The auxiliary additives may comprise a surfactant which can reduce the surface tension of the wafer cleaning solution, but it is not limited thereto. Specifically, the surfactant may be sodium dodecyl sulfate (SDS), sodium laureth sulfate (SLES) or a combination thereof, but it is not limited thereto.

In accordance with the instant disclosure, the wafer cleaning solution may have a pH value from 9 to 13, but it is not limited thereto. Preferably, the pH value of the wafer cleaning solution may range from 10 to 12.5.

The instant disclosure also provides a method for cleaning a wafer, comprising steps (a) to (c). In step (a), a diced wafer which comprises a plurality of dies is provided. In step (b), the above-mentioned wafer cleaning solution is provided, and a washing process to the diced wafer is performed with the wafer cleaning solution to obtain a washed wafer. And in step (c), a rinsing process to the washed wafer is performed with water to obtain a cleaned wafer.

Preferably, the step (b) may have an operation temperature ranging from 10° C. to 75° C., but it is not limited thereto. More preferably, the step (b) may have the operation temperature ranging from 25° C. to 35° C.

Preferably, in the step (b), the washing process may apply a method comprising spraying, immersion, ultrasonic vibration or any combination thereof, but it is not limited thereto. Specifically, a spraying device may be used to spread the wafer cleaning solution in a mass of small liquid drops onto the diced wafer. Or, the diced wafer may be immersed in the wafer cleaning solution. Or, the diced wafer is immersed in the wafer cleaning solution which is vibrated by the ultrasonic vibration at the same time.

In some embodiments, when a surface of the diced wafer comprises a polymer material, the washing process in the step (b) may be performed by immersing the diced wafer into the wafer cleaning solution; wherein a duration of the immersing may range from more than 0.5 minutes to 30 minutes. Preferably, the duration may be from 0.8 minutes to 10 minutes, but it is not limited thereto. Further, the polymer material may be a molding compound comprising epoxy resin, but it is not limited thereto.

In other embodiments, when a surface of the diced wafer comprises a polymer material, the washing process in the step (b) may be performed by spraying the wafer cleaning solution onto the surface of the diced wafer; wherein a spraying duration may range from more than 1 minute to 30 minutes. Preferably, the spraying duration may be from 2 minutes to 15 minutes, but it is not limited thereto.

In some embodiments, when a surface of the diced wafer comprises a silicon material, the washing process in the step (b) may be performed by immersing the diced wafer into the wafer cleaning solution; wherein a duration the immersing may range from more than 0.5 minutes to 30 minutes. Preferably, the duration may be from 0.8 minutes to 10 minutes, but it is not limited thereto.

In other embodiments, when a surface of the diced wafer comprises a silicon material, the washing process in the step (b) may be performed by spraying the wafer cleaning solution onto the surface of the diced wafer; wherein a spraying duration may range from more than 1 minute to 30 minutes. Preferably, the spraying duration may be from 2 minutes to 15 minutes, but it is not limited thereto.

In some embodiments, the washing process in the step (b) may be performed by the following: first, the diced wafer is immersed into the wafer cleaning solution for 0.5 minutes to 10 minutes, and then the diced wafer is taken out; next, the wafer cleaning solution is continuously sprayed onto the surface of the diced wafer after immersing for 1 minute to 10 minutes, so as to obtain the washed wafer.

Preferably, in the step (c), the rinsing process may apply a method comprising spraying, but it is not limited thereto.

Preferably, the step (c) may comprise step (c1) and step (c2). In the step (c1), the rinsing process is performed to the washed wafer with the water to obtain a wafer after finishing wet cleaning; and in the step (c2), a dry process is performed to the wafer after finishing wet cleaning to obtain the cleaned wafer.

Preferably, an operation temperature of the step (c1) may range from 10° C. to 75° C., but it is not limited thereto. More preferably, the step (c1) May have the operation temperature ranging from 25° C. to 40° C. Preferably, a duration of the step (c1) may range from 1 minute to 10 minutes, but it is not limited thereto.

Preferably, in the step (c2), the drying process may comprise adopting nitrogen gas or a clean dry air (CDA) to remove liquid (e.g. water or residual wafer cleaning solution) on the surface of the wafer after finishing wet cleaning; wherein an operation duration of the step (C2) may range from 1 minute to 5 minutes.

In some embodiments, the method for cleaning a wafer may comprise the step (b) and the step (c1) repeatedly, and the step (b) and the step (c1) are performed alternately at least once. For example, the method for cleaning a wafer may carry out the step (b), the step (c1), the step (b) and the step (c1) in order, but it is not limited thereto.

In some embodiments, the wafer cleaning solution may be provided vertically to the surface of the diced wafer (i.e., perpendicular to the surface of the diced wafer at an angle of 90°. In other embodiments, the wafer cleaning solution may be provided obliquely to the surface of the diced wafer (i.e., not perpendicular to the surface of the diced wafer at an angle of more than 0° and smaller than 90°; for example, 30° to 50°, but it is not limited thereto.)

In the specification, a range represented by “a lower-endpoint value to an upper-endpoint value”, if not particularly specified, indicates that the range is more than or equal to the lower-endpoint value and less than or equal to the upper-endpoint value. For example, “the operation temperature ranging from 10° C. to 75° C.” indicates that the operation temperature in a range of “more than or equal to 10° C. and less than or equal to 75° C.”.

### BRIEF DESCRIPTION OF THE DRAWINGS

FIG. 1 is a schematic flow diagram illustrating the method for cleaning a wafer of the instant disclosure.

FIG. 2 is an SEM image of the cleaned wafer obtained in Example 3.

FIG. 3 is an SEM image of the cleaned wafer obtained in Comparative Example 3.

FIG. 4 is an SEM image of the cleaned wafer obtained in Comparative Example 4.

FIG. 5 is an SEM image of the cleaned wafer obtained in Comparative Example 5.

### DETAILED DESCRIPTION OF THE EXEMPLARY EMBODIMENTS

Hereinafter, multiple examples are provided to illustrate the implementation of the wafer cleaning solution and the method for cleaning a wafer of the instant disclosure, while multiple comparative examples are provided as comparison. A person having ordinary skill in the art can easily realize the advantages and effects of the instant disclosure from the following examples and comparative examples. The descriptions proposed herein are just preferable embodiments for the purpose of illustrations only, not intended to limit the scope of the instant disclosure. Various modifications and variations could be made in order to practice or apply the instant disclosure without departing from the spirit and scope of the instant disclosure.

### Example 1, Example 2, Comparative Example 1 and Comparative Example 2: Wafer Cleaning Solution

The specific ingredients and the content (unit: weight percentage (wt %)) of each ingredient of the wafer cleaning solutions of Example 1 (E1), Example 2 (E2), Comparative Example 1 (CE1) and Comparative Example 2 (CE2) were respectively listed in Table 1 below. The main difference therebetween lies in the composition or content thereof.

TABLE 1
the composition and the content thereof of Examples 1, 2 and
Comparative Examples 1, 2 of the wafer cleaning solution

| Composition | E1 | E2 | CE1 | CE2 |
|---|---|---|---|---|
| MEA | 3 wt % | 3 wt % | — | 21 wt % |
| DEA | 1 wt % | 0 | — | 0 |
| Total amount | 4 wt % | 3 wt % | | 21 wt % |
| of the | | | | |
| alkanolamide | | | | |
| compound | | | | |
| ETB | 7 wt % | 7 wt % | — | 49 wt % |
| DB | 5 wt % | 0 | — | 0 |
| Total amount | 12 wt % | 7 wt % | — | 49 wt % |
| of the glycol | | | | |
| ether solvent | | | | |
| Water | 84 wt % | 90 wt % | 100 wt % | 30 wt % |
| pH value | 12 | 11 | 7 | 12 |

### Examples 3 to 6 and Comparative Examples 3 to 5: Method for Cleaning a Wafer

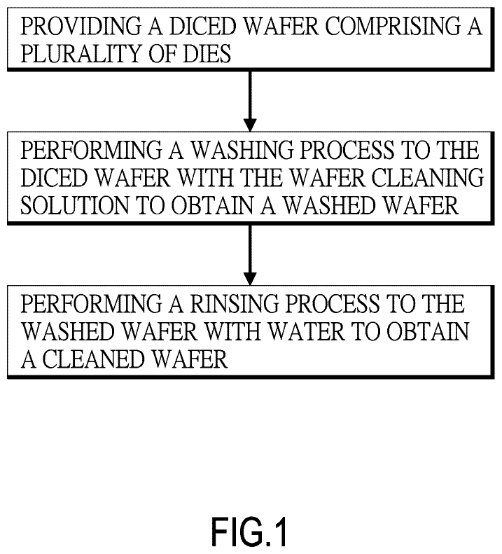

With reference to FIG. 1 showing the flow diagram of the method for cleaning a wafer, Examples 3 to 6 (E3 to E6) and Comparative Examples 3 to 5 (CE3 to CE5) respectively use the wafer cleaning solution in Table 1 to perform the cleaning process on the samples of the diced wafer, wherein the wafer cleaning solutions used in Examples 3 to 6 and Comparative Examples 3 to 5 are shown in Table 2-1 and Table 2-2.

First, in the step (a), a sample of the diced wafer was provided. Wherein, Examples 3, 4 and Comparative Examples 3 to 5 respectively used the diced wafer whose surface comprised the polymer material (molding compound) as samples; Examples 5 and 6 respectively used the diced wafer whose surface comprised the silicon material as samples.

Next, in the step (b), a washing process to the sample of the diced wafer was performed with the above-mentioned wafer cleaning solution to obtain the washed wafer in each group. Wherein, the operation temperature of the step (b) was 25° C. Each sample was put in the wafer cleaning solution by spraying or immersion, and the duration (i.e. the time of continuous operation) of each of Examples and Comparative Examples was shown in Table 2-1 and Table 2-2.

In the step (c1), the rinsing process was performed to the washed wafer with the water to obtain a wafer after finishing wet cleaning. Wherein the operation temperature of the step (c1) was 25° C.; the rinsing process was carried out by continuous spraying, and the continues spraying duration was 2 minutes. Next, in the step (c2), the wafer after finishing wet cleaning was subjected to a drying process, and finally the sample of the cleaned wafer was obtained. The drying process was carried out by blowing nitrogen gas to remove liquid from the surface of the wafer after finishing wet cleaning for 2 minutes at 25° C.

### Test Example 1: Reliability Test

Those samples of the cleaned wafers obtained from Examples 3 to 6 and Comparative Examples 3 to 5 were further placed in a high temperature (85° C.) and high humidity (85±5%) environment for 5 days, and then taken out. Next, the surfaces of samples of each group were observed by using a scanning electron microscope (SEM).

If there was no copper silicide or significant attachments on the surface of the sample to be observed, it would be evaluated as “effective cleaning”. Conversely, if there were copper silicide or significant attachments on the surface of the sample to be observed, it would be evaluated as “ineffective cleaning”. The analysis results of samples for each group were respectively recorded in Table 2-1 and Table 2-2.

TABLE 2-1
wafer cleaning solution, kind of diced wafer, the method
adopted in the washing process in the step (b) and the
duration thereof, and the reliability test result in
Examples 3 to 6 of the method for cleaning a wafer

| Group | E3 | E4 | E5 | E6 |
|---|---|---|---|---|
| Wafer cleaning | E1 | | E2 | |
| solution | | | | |
| Kind of diced | Surface comprising the | | Surface comprising the | |
| wafer | polymer material | | silicon material | |
| Method used in | immersion | spraying | Immersion | Spraying |
| the washing | | | | |
| process | | | | |
| Duration | 1 minute | 3 minutes | 1 minute | 3 minutes |
| Result | Effective | Effective | Effective | Effective |
| | cleaning | cleaning | cleaning | cleaning |

TABLE 2-2
wafer cleaning solution, kind of diced wafer, the method
adopted in the washing process in the step (b) and the duration
thereof, and the reliability test result in Comparative
Examples 3 to 5 of the method for cleaning a wafer

| Group | CE3 | CE4 | CE5 |
|---|---|---|---|
| Group of wafer | CE1 | CE2 | |
| cleaning | | | |
| solution | | | |
| Kind of diced | Surface comprising the | Surface comprising the | |
| wafer | polymer material | silicon material | |
| Method used in | immersion | immersion | Spraying |
| the washing | | | |
| process | | | |
| Duration | 5 minutes | 1 minute | 3 minutes |
| Result | Ineffective cleaning | Ineffective | Ineffective |
| | | cleaning | cleaning |

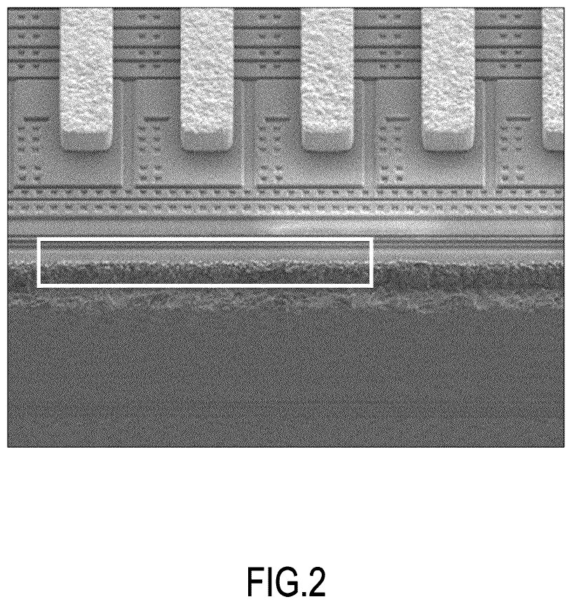

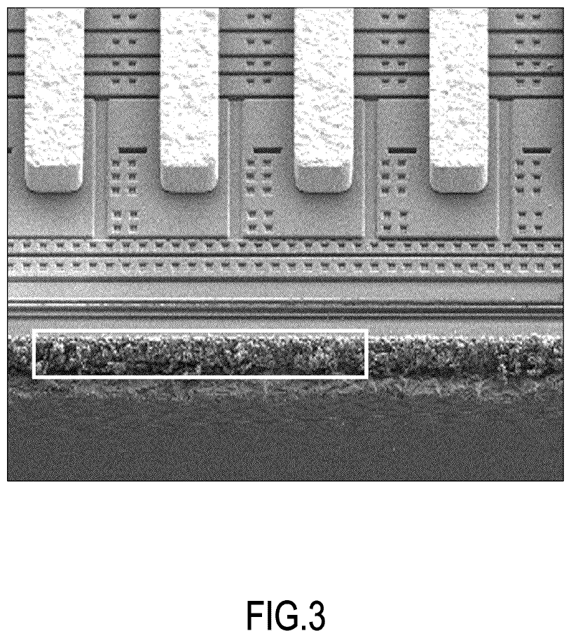

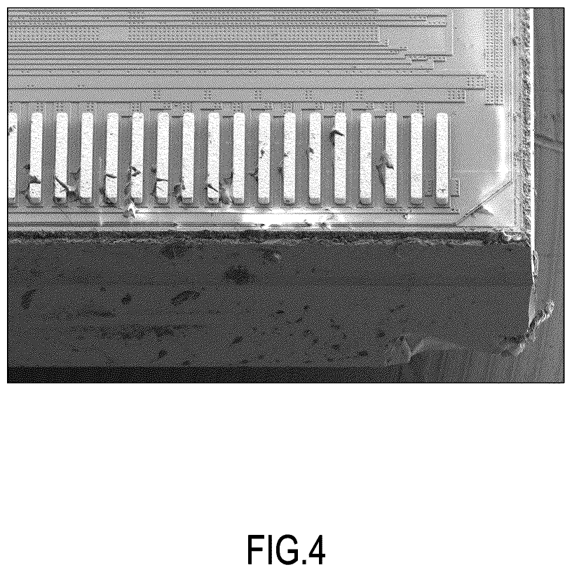

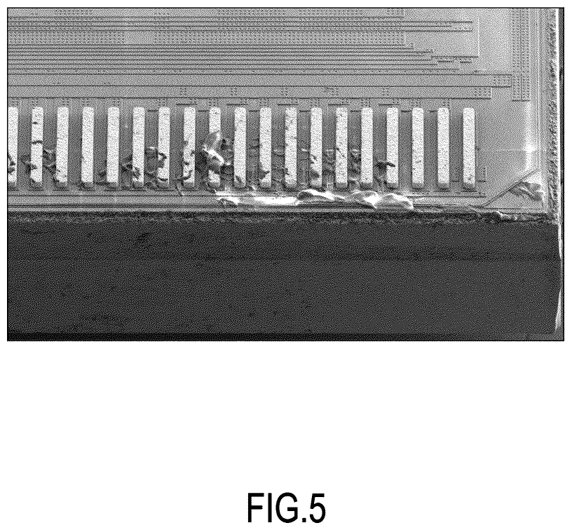

Further, the SEM image of the cleaned wafer obtained from Example 3 was taken under the conditions of an accelerating voltage of 5 kilovolts (kV) and a magnification of 50 times, and the result was shown in FIG. 2. Also, the samples of the cleaned wafer obtained from Comparative Examples 3 to 5 were respectively photographed under the same conditions, and the results were shown in FIG. 3, FIG. 4 and FIG. 5.

From the comparison between FIG. 2 and FIG. 3, it can be seen that many attachments still exist on the surface of the cleaned wafer in the framed area in FIG. 3. By contrast, the similar area in FIG. 2 is much flatter and cleaner. It demonstrates that the wafer cleaning solution of the instant disclosure indeed can remove dicing residues and inhibit the formation of copper oxide and/or copper silicide on the side of the dies.

Besides, there are many defects obviously on the side of the cleaned wafer in the framed area in FIG. 4; in addition, there are still many attachments obviously on the top surface of the cleaned wafer in the framed area in FIG. 5. Those results show that even though the total weight of the alkanolamide compound and the glycol ether solvent of the wafer cleaning solution of Comparative Example 2 is much more than that of the wafer cleaning solution of Example 1, the cleaning results of FIG. 4 and FIG. 5 are evidently worse than the cleaning result if FIG. 2. That is, if the water content in the wafer cleaning solution is not enough, the specific components (the alkanolamide compound and the glycol ether solvent) contained in the cleaning solution may reduce the function of cleaning; moreover, the wafer cleaning solution of Comparative Example 2 fails to form a protective film on the surface of the dies of the wafer, but it even damages the surface of the dies of the wafer, thereby reducing the yield.

In summary, the wafer cleaning solution and the method for cleaning a wafer using the same of the instant disclosure can clean wafers simply and quickly without a large amount of water, so it is also cost-effective. Furthermore, wafers treated with the wafer cleaning solution of the instant disclosure can prevent the formation of copper oxide and/or silicide on the sides of the dies of the cleaned wafer and avoid further chemical reactions. Therefore, the instant disclosure is conducive to maintain the quality of dies for subsequent applications. As a result, the resulting cleaned wafers finally can have the advantage of improved yield in subsequent applications.

Even though numerous characteristics and advantages of the instant disclosure have been set forth in the foregoing description, together with details of the structure and features of the instant disclosure, the disclosure is illustrative only. Changes may be made in the details, especially in matters of shape, size, and arrangement of parts within the principles of the instant disclosure to the full extent indicated by the broad general meaning of the terms in which the appended claims are expressed.

What is claimed is:

1. A wafer cleaning solution comprising:
water;
an alkanolamide compound; and
a glycol ether solvent;
wherein the alkanolamide compound comprises ethanolamine, diethanolamine or a combination thereof;
the glycol ether solvent comprises ethylene glycol mono-tert-butyl ether, diethylene glycol monobutyl ether or a combination thereof;
wherein a ratio of a total weight of the alkanolamide compound and the glycol ether solvent to a weight of the water is from 1:5 to 1:9.5;
wherein a weight ratio of the alkanolamide compound to the glycol ether solvent is from 1:20 to 1:1.5.

2. The wafer cleaning solution as claimed in claim 1, wherein the alkanolamide compound is the combination of ethanolamine and diethanolamine; wherein a weight ratio of ethanolamine to diethanolamine is from 2:1 to 5:1.

3. The wafer cleaning solution as claimed in claim 2, wherein the alkanolamide compound is the combination of ethanolamine and diethanolamine; wherein a weight ratio of ethanolamine to diethanolamine is from 2:1 to 4:1.

4. The wafer cleaning solution as claimed in claim 1, wherein the glycol ether solvent is the combination of ethylene glycol mono-tert-butyl ether and diethylene glycol monobutyl ether; wherein a weight ratio of ethylene glycol mono-tert-butyl ether to diethylene glycol monobutyl ether is from 1:1 to 1:4.

5. The wafer cleaning solution as claimed in claim 4, wherein the glycol ether solvent is the combination of ethylene glycol mono-tert-butyl ether and diethylene glycol monobutyl ether; wherein a weight ratio of ethylene glycol mono-tert-butyl ether to diethylene glycol monobutyl ether is from 1:1 to 1:2.

6. The wafer cleaning solution as claimed in claim 1, wherein the weight ratio of the alkanolamide compound to the glycol ether solvent is from 1:5 to 1:2.

7. The wafer cleaning solution as claimed in claim 1, wherein the ratio of the total weight of the alkanolamide compound and the glycol ether solvent to the weight of the water is from 1:7.5 to 1:9.5.

8. The wafer cleaning solution as claimed in claim 1, wherein the wafer cleaning solution consists of the water, the alkanolamide compound and the glycol ether solvent.

9. The wafer cleaning solution as claimed in claim 1, wherein the wafer cleaning solution further comprises a surfactant.

10. The wafer cleaning solution as claimed in claim 1, wherein the wafer cleaning solution has a pH value from 10 to 12.5.

11. A method for cleaning a wafer, comprising steps of:
step (a): providing a diced wafer which comprises a plurality of dies;
step (b): providing the wafer cleaning solution as claimed in claim 1, and performing a washing process to the diced wafer with the wafer cleaning solution to obtain a washed wafer; and
step (c): performing a rinsing process to the washed wafer with water to obtain a cleaned wafer.

12. The method as claimed in claim 11, wherein the step (b) has an operation temperature ranging from 10° C. to 75° C.

13. The method as claimed in claim 11, wherein the step (c) comprises:
step (c1): performing the rinsing process to the washed wafer with the water to obtain a wafer after finishing wet cleaning; and
step (c2): performing a dry process to the wafer after finishing wet cleaning to obtain the cleaned wafer.

14. The method as claimed in claim 11, wherein the washing process in the step (b) applies a method comprising spraying, immersion, ultrasonic vibration or any combination thereof.

15. The method as claimed in claim 11, wherein the rinsing process in the step (c) applies a method comprising spraying.

16. The method as claimed in claim 11, wherein a surface of the diced wafer comprises a polymer material; the washing process in the step (b) is performed by immersing the diced wafer into the wafer cleaning solution; wherein a duration of the immersing ranges from more than 0.5 minutes to 30 minutes.

17. The method as claimed in claim 12, wherein a surface of the diced wafer comprises a polymer material; the washing process in the step (b) is performed by immersing the diced wafer into the wafer cleaning solution; wherein a duration of the immersing ranges from 0.8 minutes to 10 minutes.

18. The method as claimed in claim 11, wherein a surface of the diced wafer comprises a silicon material; the washing process in the step (b) is performed by immersing the diced wafer into the wafer cleaning solution; wherein a duration of the immersing ranges from more than 0.5 minutes to 30 minutes.

19. The method as claimed in claim 13, wherein a surface of the diced wafer comprises a silicon material; the washing process in the step (b) is performed by immersing the diced wafer into the wafer cleaning solution; wherein a duration of the immersing ranges from more than 0.5 minutes to 30 minutes.
